(19) United States
(12) Patent Application Publication
(10) Pub. No.: US 2002/0093108 A1
(43) Pub. Date: Jul. 18, 2002

(54) Flip chip packaged semiconductor device having double stud bumps and method of forming same

(76) Inventor: Ilya L. Grigorov, Los Angeles, CA (US)

Correspondence Address: Anddrew J. Rudd, Renner, Otto, Boisselle & Sklar, LLP, 19th Floor, 1621 Euclid Ave., Cleveland, OH, 44115, US

(21) Appl. No.: 09/760,951

(22) Filed: Jan. 15, 2001

(51) Int. Cl. H01L 23/48; H01L 21/44; H01L 21/48; H01L 21/50

(52) U.S. Cl. 257/781; 438/108; 438/613

(57) ABSTRACT

A semiconductor device including a substrate having a contact pad with a first stud bump formed thereon and an integrated circuit having a contact pad with a second stud bump formed thereon. In this semiconductor device, the first stud bump is bonded to the second stud bump, thereby connecting the integrated circuit to the substrate.

### TECHNICAL FIELD

The present invention relates generally to a flip chip packaged semiconductor device. More particularly, the present invention relates to a flip chip packaged semiconductor device in which stud bumps are formed on contact pads of both an integrated circuit and a substrate and the integrated circuit and substrate are connected by bonding the stud bumps formed on the integrated circuit to the stud bumps formed on the substrate.

### BACKGROUND OF THE INVENTION

The current trend towards the miniaturization of semiconductor devices has placed greater demands on the ability of semiconductor manufacturers to establish efficient, reliable mechanical and electrical connections between an integrated circuit or die (these terms will be used interchangeably throughout) and a substrate. Three of the more common methods for connecting the die to the substrate are wire bonding, face-up tape-automated bonding, and flip chip packaging. Flip chip packaging has often emerged as the preferred method for packaging of semiconductor devices because it allows semiconductor device manufacturers more readily to connect high-density integrated circuits to a substrate. Specifically, flip chip packaging offers advantages over the other bonding methods such as shorter conductive leads from the die to the substrate, a small semiconductor device footprint, low inductance, and good noise control.

Flip chip packaging of semiconductor devices has been used in production since the mid 1960's. In one of the more common forms of flip chip packaging (termed C4 for Controlled Collapse Chip Connection), a solder bump is deposited on a contact pad of an integrated circuit. The integrated circuit is aligned with a substrate so that the solder bumps are directly over a corresponding contact pad located on the substrate. The solder bump is tacked to the contact pad of the substrate and reflowed, thereby creating an electrical and mechanical connection between the integrated circuit and the substrate. In other words, sufficient heat and pressure are applied to the integrated circuit and the substrate to compress the solder bump against the contact pad and reflow the solder, thereby forming the electrical and mechanical connection.

For several reasons, solder bumps are not practical for all applications. For example, additional wafer level processing may be required in order to enable the creation of solder bumps on the contact pads. This additional processing may be undesirable for certain applications. In such instances, alternate bump structures have been employed. One such alternate bump structure is called a stud bump. A stud bump is formed using a standard wire bonding technique. In this technique, a metallic wire (usually gold) is passed through a hollow capillary and a small portion of the wire extending beneath the capillary is melted. The surface tension of the molten metal forms a ball as the wire solidifies. The ball is compressed against a contact pad or electrode of an integrated circuit with sufficient pressure and heat to cause deformation and atomic interdiffusion of the ball and the underlying contact pad, thereby mechanically and electrically connecting the ball and the contact pad. This process of applying heat in combination with pressure is called thermocompression. The wire is then cut relatively close to a top surface of the ball, leaving behind a small portion of the wire, or stud, attached to the ball.

Traditionally, stud bumps have been formed on either the contact pads of the integrated circuit or the contact pads of the substrate. To attach the integrated circuit to the substrate, the stud bumps are aligned with corresponding unbumped contact pads of either the integrated circuit or the substrate. Thermocompression is then used to connect electrically and mechanically the stud bump to the unbumped contact pad.

In many instances, the metal traces or metallization forming the contact pads of either the integrated circuit or the substrate have a marginal ability to bond to the stud bump during thermocompression. The degradation in the ability of the metallization to bond could be a result of the relative thickness of the metal, or rather the lack thereof. Alternatively, the degradation could be a result of growth of an additional layer of material, such as a glass binder, over the metallization prior to connection of the integrated circuit and the substrate.

In cases where the metallization is marginal, problems can occur. In some instances, the pressure and temperature required to form the electrical and mechanical bond between the stud bump and the contact pad may have to increase substantially. The application of increased heat and pressure results in a stud bump of lower height and larger diameter, which, in turn, may result in shorting of adjacent contacts due to the “spread” of the stud bump. Alternatively, the increased thermomechanical stress imposed on the stud bump may result in a weaker bond that is incapable of withstanding stresses imparted on the semiconductor device either during the remaining manufacturing steps or during its use. In such instances “disbanding” may occur, thereby rendering the semiconductor device virtually useless.

The lower height of the stud bumps may also create problems during subsequent steps of the semiconductor device manufacturing process. For example, the mismatch of the coefficients of thermal expansion of the integrated circuit and the substrate causes stress to build up in the bonds joining the two. To help reduce this stress, an underfill encapsulant material, such as a polymer, is introduced in the gap formed between the integrated circuit and the substrate after connection. Generally, this polymer flows by capillary action to fill the gap. However, if the stud bump is shorter, then the gap is correspondingly smaller. For reasons that will be discussed more fully below, the smaller gap negatively affects the capillary action of the polymer, potentially making this process step, among other things, more time consuming and hence more expensive.

### SUMMARY OF THE INVENTION

The present invention provides a semiconductor device in which connections between the integrated circuit and the substrate are sufficiently strong and reliable to withstand the stresses placed on the device both during its manufacture and during its use. Furthermore, the present invention provides a semiconductor device having a sufficient gap between the integrated circuit and the substrate to minimize the limiting effect that such gap has on subsequent manufacturing steps.

In accordance with one aspect of the present invention, a semiconductor device is provided which includes a substrate having a contact pad with a first stud bump formed thereon and an integrated circuit having a contact pad with a second stud bump formed thereon. The first stud bump is bonded to the second stud bump, thereby connecting the integrated circuit to the substrate.

In accordance with another aspect of the present invention, a semiconductor device is provided in which a gap formed between the integrated circuit and the substrate is filled with an epoxy that includes an inorganic filler having a particle size in the range of approximately 2 microns to 25 microns.

In accordance with still another aspect of the present invention, a method of packaging a semiconductor device having an integrated circuit and a substrate is provided that includes the steps of forming a first stud bump on at least one contact pad located on the substrate, forming a second stud bump on at least one contact pad located on the integrated circuit, and bonding together the first stud bump and the second stud bump.

In accordance with still a further aspect of the present invention, a method of packaging a semiconductor device is described. The method includes the steps of providing a substrate having a first stud bump formed on at least one contact pad located thereon, providing an integrated circuit having a second stud bump formed on at least one contact pad located thereon, and bonding together the first stud bump and the second stud bump.

### BRIEF DESCRIPTION OF THE DRAWINGS

FIG. 1 is a cross sectional view of a semiconductor device in accordance with the present invention prior to the integrated circuit and the substrate being connected.

FIG. 2 is a cross sectional view of a semiconductor device in accordance with the present invention after the integrated circuit and the substrate are connected.

FIG. 3 is a cross sectional view of a semiconductor device in accordance with the present invention showing the gap between the integrated circuit and the substrate filled with an underfill encapsulant material.

### DESCRIPTION OF THE PREFERRED EMBODIMENTS

The present invention will now be described in detail with reference to the drawings. In the drawings, like reference numerals are used to refer to like elements throughout.

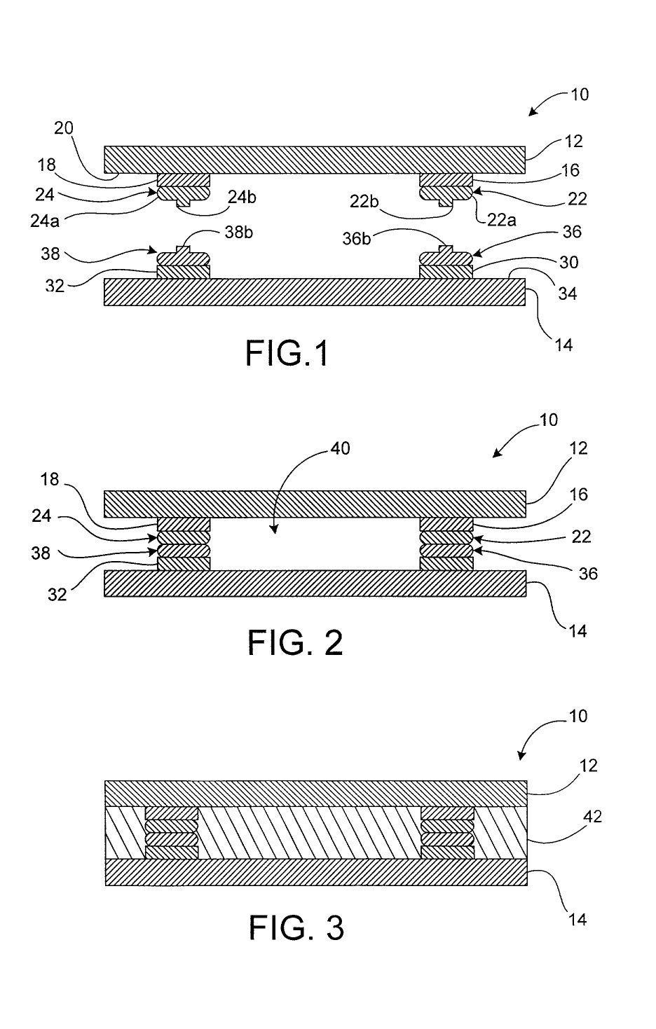

FIG. 1 illustrates components of a semiconductor device 10 in accordance with the present invention. The semiconductor device 10 includes an integrated circuit or die 12 and a substrate 14. Located on the die 12 are contact pads 16 and 18. The contact pads 16 and 18 are formed on surface 20 of the die 12 by any commonly known manufacturing technique, such as deposition and patterning, and are made of an appropriate conductive material. Aluminum generally has been the material of choice for contact pads due at least in part to aluminum's low resistivity and the ease with which it may be processed.

The stud bumps 22 and 24 are formed respectively on the contact pads 16 and 18. The stud bumps 22 and 24 are formed using a conventional wire bonding technique, which is described more fully in connection with the stud bump 22. A ball 22a is formed at the end of a metallic wire (not shown), which has been passed through a hollow capillary (also not shown). The ball 22a is then compressed against the contact pad 16 via ultrasonic incorporated thermocompression means so as to connect mechanically and electrically the ball 22a to the contact pad 16. In other words, the capillary vibrates the wire and hence the ball 22a at ultrasonic frequencies while heat and pressure are simultaneously applied to the ball 22a, thereby causing deformation and atomic interdiffusion of the ball 22a and the contact pad 16. The wire is then cut relatively close to a top surface of the ball 22a, leaving behind stud 22b. As can be appreciated by one skilled in the art, this process is then repeated to form stud bump 24 as well as any additional stud bumps to be created on the die 12.

The stud bumps 22 and 24 are preferably made of gold or gold alloy because of its easy deformation under pressure at elevated temperatures, its resistance to oxide formation, and its ball formability during the stud bump creation process. However, other metals could be used to form stud bumps 22 and 24 without departing from the scope of this invention.

The substrate 14 has contact pads 30 and 32 formed on surface 34. As with contact pads 16 and 18 formed on the die 12, the contact pads 30 and 32 are formed on the surface 34 using conventional manufacturing techniques (e.g., deposition and patterning) and are made of an appropriate conductive material, such as aluminum or gold.

The stud bumps 36 and 38 are formed respectively on the contact pads 30 and 32 using the wire bonding technique described above in connection with the stud bump 22 and are also generally made from gold or gold alloy, although other conductive metals could be employed.

After the stud bumps 22, 24, 36, and 38 have been formed, they may be coined to ensure flatness and coplanarity. More particularly a flat surface may be used to apply pressure on the order of 50 g/bump to the studs 22b, 24b, 36b, and 38b, thereby flattening a top surface of the studs 22b, 24b, 36b, and 38b and making the heights of the stud bumps 22, 24, 36, and 38 uniform with respect to the surface of the substrate or the die on which the stud bumps are located.

FIG. 2 illustrates the die 12 and the substrate 14 connected together to form semiconductor device 10. The connection process is generally accomplished using the following steps (not illustrated) and may be done using a commercial die-bonder robot. The contact pads 16 and 18 and hence the stud bumps 22 and 24 are aligned with contact pads 30 and 32 and hence stud bumps 36 and 38. Heat and pressure are applied to the die 12 and the substrate 14. This combination of heat and pressure, i.e., thermocompression, causes a deformation and atomic interdiffusion between the aligned stud bumps, thereby creating electrical and mechanical connections. That is, stud bump 22 is bonded (i.e., electrically and mechanically connected) to the stud bump 36 and the stud bump 24 is bonded to the stud bump 38.

One skilled in the art will readily appreciate that forming metallurgical bonds between identical materials is generally simpler and more effective than forming metallurgical bonds between dissimilar metals. In fact, tests were performed to determine the relative strength of the bonds formed in the structure illustrated in FIGS. 1 and 2 as compared to the strength of the bonds formed using the more conventional structure of bonding a stud bump directly to the corresponding contact pad on either the die or substrate.

Specifically, the inventor sheared the die from the substrate on all 3 structures (i.e., stud bump to stud bump, stud bump to contact pad on die, and stud bump to contact pad on substrate). Each structure had identical stud bumps, i.e., stud bumps of the same size. To determine the strength of the bonds, the force necessary to shear the die from the substrate was measured in all cases. This shear force was then normalized across the number of electrical connections or bumps in order to calculate the force per connection/bump required to break the bond. It was determined that in the cases where a stud bump was directly connected to a contact pad (regardless of the location of the contact pad), the force required to break the bond was approximately 20 to 25 grams per connection/bump and the failure occurred at the bond created during the flip-chip attachment process. In contrast, in the case where a stud bump was connected to a stud bump, the force required to break the bond was approximately 30 to 40 grams per connection/bump and the failure occurred at the bump to contact pad interface, indicating that the wire-bonding process was the limiting factor, not the flip-chip attachment process.

After connection of the die 12 and substrate 14, the semiconductor device 10 may undergo further manufacturing steps. As can be seen in FIG. 2, a gap 40 is formed between the surface 20 of the die 12 and the surface 30 of the substrate 14 after the die 12 and the substrate 14 are connected. For reasons discussed in the Background of the Invention, an underfill encapsulant material 42 may be dispensed into the gap 40. To fill the gap 40, the underfill encapsulant material 42 flows by capillary action. FIG. 3 illustrates the encapsulant material 42 after it has filled the gap 40. The encapsulant material 42 is then cured, typically by baking for an extended period of time.

The polymers of choice for the underfill encapsulant material 42 are generally epoxies. However, to optimize the effectiveness of the underfill encapsulant material 42, it is desirable that its coefficient of thermal expansion approximately match that of the stud bumps 22, 24, 36, and 38 so that additional stresses, due to mismatched coefficients of thermal expansion, are not placed on the stud bumps at the interfaces between the stud bumps and the underfill encapsulant material. The preferred epoxies generally have a coefficient of expansion in the range of 50 ppm/° C. to 80 ppm/° C. In contrast, the stud bumps 22, 24, 36, and 38 generally have a coefficient of thermal expansion in the range of approximately 20 ppm/° C. to 25 ppm/° C. In order to reduce the coefficient of thermal expansion of the epoxy to a value on the order of the coefficient of thermal expansion of the stud bumps, inorganic fillers having much lower coefficients of thermal expansion are added to the epoxy. The particle size of these inorganic fillers can vary, but a larger particle size has, in the past, had a detrimental effect on the capillary action of the underfill encapsulant material 42.

It has been found that if the particle size of the inorganic filler is greater than one-third the size of the gap 40 between the die 12 and the substrate 14, then the capillary action of the underfill encapsulant material 42 has a limiting effect which makes this manufacturing step more time consuming, more susceptible to void formation and more susceptible to the separation of the epoxy from the inorganic filler during application. However, it is commonly known that as the particle size of the inorganic fillers is reduced, the cost of the inorganic fillers, and hence the underfill encapsulant material 42, is increased.

The present invention provides for a device that has a larger gap 40 between the die 12 and the substrate 14 than would be present in a semiconductor device manufactured using only a single stud bump structure. For example, assuming the formation of stud bumps having a height of approximately 20 microns and assuming minimal deformation of the stud bump during the connection process, a semiconductor device in accordance with the present invention would have a gap 40 measuring on the order of 40 microns. In contrast, a semiconductor device in accordance with the single stud bump structure of the prior art would have a gap measuring on the order of 20 microns. Accordingly, a semiconductor device in accordance with the present invention can be underfilled with an epoxy mixed with an inorganic filler having a particle size of up to 12 to 13 microns without detrimentally impacting the capillary action of the mixture. The semiconductor device of the prior art would need to be underfilled with an epoxy mixed with an inorganic filler having a particle size of no greater than 5 to 6 microns. A particle size greater than 5 to 6 microns would negatively impact the capillary action of the underfill encapsulant material.

Thus, the underfill encapsulant material used in a semiconductor device 10 in accordance with the present invention would be less expensive than the underfill encapsulant material required to be used in a semiconductor device in accordance with the prior art. Furthermore, since the underfill encapsulant material 42 will flow more readily in the larger gap, the process step of underfilling the gap 40 in a semiconductor device 10 in accordance with the present invention would be less time consuming and hence less expensive than the corresponding process step of underfilling the gap in a semiconductor device in accordance with the prior art.

Although the invention has been shown and described with respect to certain embodiments, it is obvious that equivalents and modifications will occur to others skilled in the art upon the reading and understanding of the specification.

What is claimed is:

1. A semiconductor device comprising:
(a) a substrate including a contact pad having a first stud bump formed thereon; and
(b) an integrated circuit including a contact pad having a second stud bump formed thereon;
wherein, the first stud bump is bonded to the second stud bump, thereby connecting the integrated circuit to the substrate.

2. A semiconductor device in accordance with claim 1, wherein the substrate has a plurality of contact pads, each having a first stud bump formed thereon and the integrated circuit has a plurality of contact pads, each having a second stud bump formed thereon.

3. A semiconductor device in accordance with claim 1, wherein a gap is formed between facing surfaces of the integrated circuit and the substrate.

4. A semiconductor device in accordance with claim 3, wherein the gap has a size in the range of approximately 30 microns to approximately 100 microns.

5. A semiconductor device in accordance with claim 3, further comprising a polymer material filling the gap.

6. A semiconductor device in accordance with claim 5, wherein the polymer material is an epoxy including an inorganic filler.

7. A semiconductor device in accordance with claim 6, wherein the inorganic filler has a particle size in the range of approximately 2 microns to 25 microns.

8. A semiconductor device in accordance with claim 1, wherein the first stud bump and the second stud bump are made of gold.

9. A semiconductor device in accordance with claim 1, wherein the first stud bump and the second stud bump are made of gold alloy.

10. A method of packaging a semiconductor device having an integrated circuit and a substrate comprising the steps of:
(a) forming a first stud bump on at least one contact pad located on the substrate;
(b) forming a second stud bump on at least one contact pad located on the integrated circuit; and
(c) bonding together the first stud bump and the second stud bump.

11. A method in accordance with claim 10, wherein the step of bonding includes the step of applying heat and pressure to the integrated circuit and the substrate.

12. A method in accordance with claim 10, further comprising the step of coining the first stud bump and the second stud bump prior to bonding in order to flatten a top surface of both the first stud bump and the second stud bump.

13. A method in accordance with claim 10, further comprising the step of filling a gap formed between facing surfaces of the integrated circuit and the substrate with a polymer material.

14. A method in accordance with claim 13, wherein the polymer material is an epoxy including an inorganic filler.

15. A method in accordance with claim 14, wherein the inorganic filler has a particle size in the range of approximately 2 microns to 25 microns.

16. A method in accordance with claim 10, wherein the first stud bump and the second stud bump are formed of gold.

17. A method in accordance with claim 10, wherein the first stud bump and the second stud bump are formed of gold alloy.

18. A method in accordance with claim 10, wherein the first stud bump is formed on each of a plurality of contact pads located on the integrated circuit and the second stud bump is formed on each of a plurality of contact pads located on the substrate.

19. A method of packaging a semiconductor device comprising the steps of:
(a) providing a substrate having a first stud bump formed on at least one contact pad located on the substrate;
(b) providing an integrated circuit having a second stud bump formed on at least one contact pad located on the integrated circuit; and
(c) bonding together the first stud bump and the second stud bump.
